(19) United States
(12) Patent Application Publication
(10) Pub. No.: US 2024/0231118 A1
(43) Pub. Date: Jul. 11, 2024

(54) SYSTEMS AND METHODS OF INCOHERENT SPATIAL FREQUENCY FILTERING

(71) Applicant: PRESIDENT AND FELLOWS OF HARVARD COLLEGE, Cambridge, MA (US)

(72) Inventors: Dean Samer HAZINEH, Cambridge, MA (US); Zhujun SHI, Cambridge, MA (US); Qi GUO, Cambridge, MA (US); Todd ZICKLER, Cambridge, MA (US); Federico CAPASSO, Cambridge, MA (US)

(73) Assignee: PRESIDENT AND FELLOWS OF HARVARD COLLEGE, Cambridge, MA (US)

(21) Appl. No.: 18/559,038

(22) PCT Filed: May 4, 2022
(86) PCT No.: PCT/US2022/027708

§ 371 Date: Nov. 3, 2023

Related U.S. Application Data
(60) Provisional application No. 63/185,342, filed on May 6, 2021.

(51) Int. Cl. G02B 27/28; G01B 11/24; G02B 3/08

(52) U.S. Cl. CPC G02B 27/286; G01B 11/24; G02B 3/08; G02B 27/288

(57) ABSTRACT

Disclosed is a sensor for determining a physical characteristic, comprising a linear polarizer, a polarization-sensitive metalens, positioned between the linear polarizer and a photosensor, configured to manipulate light from a scene filtered by the linear polarizer, according to two or more phase profiles to simultaneously produce at least two spatial frequency filtered images on a surface of the photosensor, and processing circuitry configured to receive, from the photosensor, a measurement corresponding to the at least two spatial frequency filtered images, and determine, according to the measurement, a depth associated with at least one feature in the scene.

### CROSS-REFERENCE TO RELATED APPLICATIONS

The present application claims the benefit of and priority to U.S. Provisional Patent Application No. 63/185,342, filed on May 6, 2021, the contents of which is incorporated herein by reference in its entirety for all purposes.

### STATEMENT OF FEDERALLY SPONSORED RESEARCH OR DEVELOPMENT

This invention was made with government support under National Science Foundation award No. U.S. Pat. No. 1,718,012. The government has certain rights in the invention.

### BACKGROUND

Metalenses are optical elements to manipulate electromagnetic waves such as light. Metalenses may enable various applications that may be impractical to achieve with traditional diffractive lenses. For example, metalenses often have a smaller form factor than traditional diffractive lenses and are therefore suited to micro or lightweight applications.

### SUMMARY

One embodiment of the present disclosure is a sensor for determining a physical characteristic, comprising a linear polarizer, a polarization-sensitive metalens, positioned between the linear polarizer and a photosensor, configured to manipulate light from a scene filtered by the linear polarizer, according to two or more phase profiles to simultaneously produce at least two images on a surface of the photosensor, and processing circuitry configured to receive, from the photosensor, a measurement corresponding to the at least two images, and determine, according to the measurement, a physical characteristic associated with at least one feature in the scene.

In some embodiments, the light includes light having a first polarization and wherein the linear polarizer manipulates the light to produce light having a second polarization and light having a third polarization. In some embodiments, the photosensor is a polarization-sensitive photosensor. In some embodiments, a first image of the at least two images produced by the polarization-sensitive metalens includes light of a first polarization and wherein a second image of the at least two images includes light of a second polarization. In some embodiments, the measurement includes a first intensity measurement corresponding to the light of the first polarization and a second intensity measurement corresponding to the light of the second polarization. In some embodiments, determining the physical characteristic comprises determining depth associated with the at least one feature by performing fewer than four floating point operations (FLOPs) per pixel. In some embodiments, the light from the scene includes spatially incoherent light.

Another embodiment of the present disclosure is a method of generating design parameters to implement a filter, comprising determining a relationship between (i) two or more phase profiles each comprising a plurality of phase values and (ii) spatial frequency characteristics of electromagnetic radiation manipulated by the two or more phase profiles, performing backpropagation using the relationship to obtain a first plurality of phase values for a first phase profile of the two or more phase profiles and a second plurality of phase values for a second phase profile of the two or more phase profiles, wherein the first plurality and the second plurality of phase values collectively at least partially implement the filter, and generating a first set of design parameters that implement the first plurality of phase values and a second set of design parameters that implement the second plurality of phase values.

In some embodiments, the first set and the second set of design parameters include at least a value of a diameter, height, or width of a nanopillar. In some embodiments, the method further comprises combining the first set and the second set of design parameters to obtain two dimensions of a physical structure. In some embodiments, the physical structure includes a spatially-varying metalens. In some embodiments, the first phase profile is configured to selectively manipulate electromagnetic radiation having a first polarization and wherein the second phase profile is configured to selectively manipulate electromagnetic radiation having a second polarization. In some embodiments, the first plurality of phase values implement a first filter, the second plurality of phase values implement a second filter, and applying an operation on intensity values of electromagnetic radiation manipulated by the first plurality and the second plurality of phase values, at least partially implements the filter. In some embodiments, the operation includes subtraction.

Another embodiment of the present disclosure is an attachment for a polarization-sensitive imaging device, comprising a polarization-sensitive metalens, positioned between a filter and a photosensor, configured to manipulate light from a scene filtered by the filter according to two or more phase profiles to simultaneously produce at least two images on a surface of the photosensor, and wherein each of the two or more phase profiles implemented by the polarization-sensitive metalens establishes a spatial frequency filter to manipulate the filtered light.

In some embodiments, the light includes light having a first polarization and wherein the filter manipulates the light to produce light having a second polarization and light having a third polarization. In some embodiments, a first image of the at least two images produced by the polarization-sensitive metalens includes light of a first polarization and wherein a second image of the at least two images includes light of a second polarization. In some embodiments, the polarization-sensitive imaging device is configured to measure an intensity associated with the at least two images, the measurement including a first intensity measurement corresponding to the light of the first polarization and a second intensity measurement corresponding to the light of the second polarization. In some embodiments, the polarization-sensitive imaging device is configured to determine a depth associated with at least one feature in the scene using the measurement, wherein determining the depth includes performing three floating point operations (FLOPs) per pixel. In some embodiments, the light from the scene includes spatially incoherent light.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1 is a block diagram illustrating a system for determining depth using spatial frequency filtering, according to an example embodiment;

FIG. 2A is a schematic diagram illustrating an opto-electronic filtering system, according to an example embodiment;

FIG. 2B is a number of plots illustrating characteristics of the metalens of FIG. 2A, according to an example embodiment;

FIG. 3 is a schematic diagram illustrating a system for determining depth, according to an example embodiment;

FIG. 4 is a number of diagrams illustrating phase-profile design to achieve a spatial frequency filter, according to an example embodiment;

FIG. 5 is a number of diagrams illustrating spatial frequency filtering using two phase-profiles, according to an example embodiment;

FIG. 6A is a number of diagrams illustrating various characteristics of a number of phase-profiles, according to an example embodiment;

FIG. 6B is a number of diagrams illustrating various characteristics of a simulated image, according to an example embodiment; and

FIG. 7 is a plot illustrating depth sensing performance, according to an example embodiment.

### DETAILED DESCRIPTION

Referring now generally to the Figures, described herein are systems and methods of determining depth using spatial frequency filtering. Measurement or determination of physical characteristics, such as depth sensing (e.g., determining distances to objects in an image, etc.), is often useful and/or necessary in various fields. For example, autonomous driving systems may capture images of the surroundings of a vehicle and determine distances to objects in the images to avoid collision. Depth sensors often rely on optical instruments such as an aperture, lens, and photosensor to capture information to generate depth measurements. For example, a camera may capture an image used to generate a depth measurement. Traditionally, depth sensing is achieved by capturing an image having a first depth of field (e.g., focal distance, etc.), operating a lens (e.g., mechanically interacting with a diffractive lens, etc.) to achieve a second depth of field, capturing an image having the second depth of field, and comparing the first and second images to determine a distance to an object in the first and second images. Such a system may suffer from poor exposure, lack of contrast in the images, bulkiness, or object motion. For example, a traditional depth sensor may introduce a time delay between capturing the first image and the second image during which objects in the image may have moved (e.g., obstacles in a dynamic scene such as a high speed car pursuit, etc.) which may make comparisons between the images difficult, thereby impairing and/or thwarting traditional depth sensing techniques. As another example, a traditional depth sensor may require multiple lenses which make the systems bulky and/or large and impractical for many applications (e.g., embedded systems in drones, etc.).

Some depth sensors may improve upon traditional depth sensing techniques by utilizing nanophotonic structures. However, these traditional nanophotonic structures may only be usable with spatially coherent light, thereby making them impractical in various applications (e.g., autonomous vehicles, drones, vision systems, etc.). Moreover, many traditional depth sensors rely on digital image processing such as the application of digital filters. For example, a traditional depth sensor may require 2,500 or more floating point operations (FLOPs) per pixel to determine a depth. This may be impractical in various applications such as resource-constrained embedded systems. Therefore, systems and methods for improved depth sensing/depth detection are needed.

One solution is a compact opto-electronic approach to image processing with spatially incoherent light based on an inverse-designed metalens. Specifically, systems and methods of the present disclosure facilitate design of a metalens (e.g., including a metasurface, nanopillars, etc.) that implements a spatial frequency filter, thereby effectively offloading computational costs to the metalens. In various embodiments, the depth sensing system of the present disclosure may facilitate determining depth (or other physical characteristics, such as edge detection) with as few as three FLOPs per pixel. In some embodiments, the depth sensing system may determine depth using a single digital division. The depth sensing system of the present disclosure may provide various advantages over existing systems. For example, the depth sensing system of the present disclosure may require significantly fewer computational operations than traditional systems, thereby saving computational power and energy. Moreover, the depth sensing system of the present disclosure may facilitate single-shot depth sensing without the need for moving parts (e.g., such as in “depth from defocus” systems, etc.), thereby eliminating issues arising from object motion. In various embodiments, the depth sensing system of the present disclosure facilitates compact depth sensing without the need for bulky optics, thereby enabling small lightweight applications such as embedded depth sensing within small aerial drones. Moreover, the depth sensing system of the present disclosure is usable with spatially incoherent light, thereby enabling a range of applications previously not possible with spatially coherent light only systems.

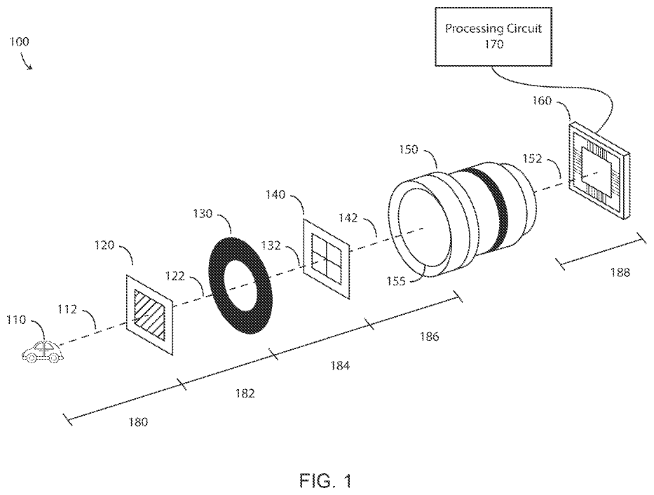

Referring now to FIG. 1, system 100 for determining depth is shown, according to an example embodiment. In various embodiments, system 100 may facilitate determining a physical characteristic associated with a feature in a scene. For example, system 100 may facilitate determining a depth and/or a detected edge associated with a feature in a scene. Additionally or alternatively, system 100 may determine spectral information (e.g., color). For example, system 100 may be used to determine colors in a scene without the need for a Bayer filter. In some embodiments, system 100 may enable hyperspectral imaging. For example, system 100 may be used for fluorescence imaging in microscopy. Additionally or alternatively, system 100 may facilitate low computation object recognition (e.g., by structuring the frequency response of the system, etc.). System 100 is shown to include object 110, polarizer 120, aperture 130, metalens 140, optics 150, image sensor 160, and processing circuit 170. In various embodiments, system 100 includes greater, fewer, and/or different components than shown in FIG. 1. For example, in some embodiments system 100 may not include optics 150. In various embodiments, system 100 includes spacings 180-188 between components of system 100. For example, spacing 184 may be a distance from a back surface of aperture 130 to a front surface of metalens 140. Object 110 may be an object imaged by system 100. For example, object 110 may be a scene having a plurality of elements and system 100 may determine a depth (e.g., a distance from sensor 160 or another reference point to each of the plurality of elements, etc.) associated with each of the plurality of elements. Polarizer 120 may receive incident light 112 and may polarize incident light 112 to produce polarized light 122. In various embodiments, polarizer 120 includes an optical linear polarizer such as a linear polarizer with a principle axis oriented 45° relative to an x-axis of metasurface 140. In some embodiments, polarizer 120 includes a spectral filter such as a spectral filter implementing a bandpass filter.

Aperture 130 may receive incident light such as polarized light 122 and may allow a portion of the incident light to pass to produce reduced light 132. In various embodiments, aperture 130 is a variable aperture. Additionally or alternatively, aperture 130 may be a fixed aperture such as a pinhole aperture. In some embodiments, system 100 does not include aperture 130. For example, system 100 may use a polarization sensitive metalens in addition to or as a substitute for aperture 130. Metalens 140 may modify/manipulate incident light. For example, metalens 140 may modify/adjust/manipulate a phase, amplitude, polarization, depth of field, direction, and/or the like of incident light. In some embodiments, metalens 140 spatially multiplexes incident light to produce one or more images. In various embodiments, the one or more images have different characteristics (e.g., different phases, etc.) as described in detail below. In various embodiments, metalens 140 is or includes a metasurface. A metasurface may be an ultrathin planar optical component composed of subwavelength-spaced nanostructures patterned at an interface. In various embodiments, the individual nanostructures facilitate controlling phase, amplitude and polarization of a transmitted wavefront at subwavelength scales (e.g., allowing multiple functions to be multiplexed within a single device, etc.). Metalens 140 may be constructed of or otherwise include titanium dioxide (TiO₂) nanopillars. In various embodiments, metalens 140 receives incident light such as reduced light 132 and manipulates the incident light to produce modified light 142.

Optics 150 (e.g., an optical assembly/system/device) may be or include one or more optical components such as a diffractive lens (e.g., made of glass or other materials, etc.). In various embodiments, optics 150 receive incident light such as modified light 142 and modify the incident light to produce conformed light 152. In various embodiments, the system of the present disclosure is usable to modify existing cameras to facilitate depth sensing or determination of other physical characteristic(s). For example, an existing camera may include optics 150 and image sensor 160 and system 100 may couple polarizer 120, aperture 130, and/or metalens 140 to optics 150 to convert the existing camera to facilitate depth sensing. In some embodiments, system 100 does not include optics 150. In some embodiments, optics 150 includes optics aperture 155. Optics aperture 155 may pass a portion of incident light into optics 150.

Image sensor 160 may measure incident light such as conformed light 152 or modified light 142. In various embodiments, image sensor 160 is a digital photosensor configured to measure various parameters associated with incident light such as intensity, wavelength, phase, etc. Image sensor 160 may be a charge-coupled device (CCD), complimentary metal-oxide-semiconductor (CMOS) device, and/or any other photosensor known in the art. In some embodiments, image sensor 160 has a high frame rate (e.g., 160 frames-per-second, etc.). In some embodiments, image sensor 160 is a polarization sensitive photosensor. For example, image sensor 160 may include a polarization micro-array positioned between the incident light and each pixel of the photosensor. The polarization micro-array may include one or more linear polarizers oriented in various directions such as 0°, 45°, and/or 90°. In various embodiments, image sensor 160 generates a measurement of one or more images. For example, metalens 140 may produce two images on image sensor 160 and image sensor 160 may generate a measurement including intensity values for the two images. Additionally or alternatively, image sensor 160 may generate a measurement including color values.

Processing circuit 170 may analyze the measurement from image sensor 160 to generate a depth map for instance, as described in detail below. In various embodiments, processing circuit 170 includes a processor and memory. The memory may have instructions stored thereon that, when executed by the processor, cause processing circuit 170 to perform the various operations described herein. The operations described herein may be implemented using software, hardware, or a combination thereof. Processing circuit 170 may include a microprocessor, ASIC, FPGA, etc., or combinations thereof. In many embodiments, processing circuit 170 may include a multi-core processor or an array of processors. The memory may include, but is not limited to, electronic, optical, magnetic, or any other storage devices capable of providing the processor with program instructions. The memory may include a floppy disk, CDROM, DVD, magnetic disk, memory chip, ROM, RAM, EEPROM, EPROM, flash memory, optical media, or any other suitable memory from which the processor can read instructions. The instructions may include code from any suitable computer programming language such as, but not limited to, C, C++, C #, Java, JavaScript, Perl, HTML, XML, Python and Visual Basic

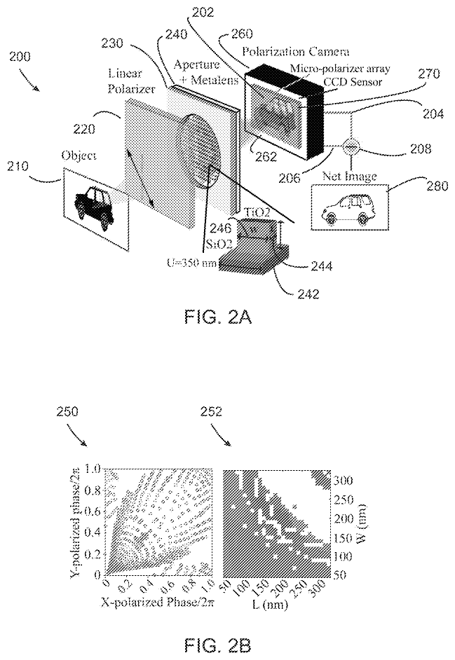

Referring now to FIGS. 2A-8, system 100 is described in greater detail. In various embodiments, spatial frequency filtering includes altering an optical field or image by selectively removing or scaling frequency components. For example, by structuring the frequency content of an image, improved contrast, noise reduction, data compression, and/or edge-detection can be achieved.

Although filtering is often applied to an image digitally post-measurement, the same transformation can instead be partially or fully achieved optically, thus substantially reducing the computational burden, power consumption, and processing time associated with digital transformations. In some embodiments, optical frequency filtering is possible using traditional systems. However, such traditional systems may only be valid for spatially coherent optical fields. Moreover, such traditional systems may require multiple lenses making the system bulky and large, and impractical or suboptimal for many applications.

In various embodiments, diffraction of spatially coherent light naturally introduces a subtraction operation via combining amplitudes with an appropriate phase shift. Systems and methods of the present disclosure may facilitate incoherent spatial frequency filtering (e.g., user-specified 2D filtering operations via appropriately co-designed phase masks). In various embodiments, systems and methods of the present disclosure improve a number of emerging applications, particularly for mobile and micro-robotic sensors where power is limited. In various embodiments, if an image to be processed contains N×N pixels (where N is usually on the order of 10³), the hybrid opto-electronic approach of the present disclosure then can involve 2N² log(N²) fewer digital floating-point operations to implement the same 2D spatial frequency filter, relative to a traditional full digital procedure. For edge-detection and image differentiation including a digital convolution of the input image with a kernel of size m×m, the hybrid opto-electronic implementation of the present disclosure can involve/use approximately (2m−1)N² or (m²−1)N² fewer floating point operations relative to a traditional full digital procedure.

In various embodiments, metalens 140 may be configured to overcome constraints of fixed object depth and narrow-bandwidth wavelength operation associated with traditional systems, thereby enabling more versatile operation.

Referring now specifically to FIG. 2A, system 200 for incoherent spatial frequency filtering is shown, according to an example embodiment. In various embodiments, system 200 is similar to system 100. For example, system 200 may implement a spatial frequency filter to facilitate depth (or other physical characteristic) determination. System 200 is shown to include object 210, linear polarizer 220, aperture 230, metalens 240, and polarization camera 260. In various embodiments, object 210 is similar to object 110. For example, object 210 may be a scene imaged by polarization camera 260. Linear polarizer 220 may be similar to polarizer 120. For example, linear polarizer 220 may include a linear polarizer oriented 45° relative to an axis of polarization camera 260. Aperture 230 may be similar to aperture 130. For example, aperture 230 may receive incident light and allow a portion of the incident light to pass to subsequent components of system 200. Metalens 240 may be similar to metalens 140. For example, metalens 240 may include a metamaterial that modifies one or more properties of incident light. In various embodiments, metalens 240 includes one or more nanostructures. For example, metalens 240 may include a nanostructure having substrate base 242, length 244, and width 246. In various embodiments, changing the properties of the one or more nanostructures of metalens 240 such as a value of length 244 and/or width 246 changes how metalens 240 modifies/manipulates/processes incident light. In various embodiments, the one or more nanostructures of metalens 240 have different dimensions. For example, a first nanostructure may have a first width and a second nanostructure may have a second width.

Polarization camera 260 may be or include an image sensor that measures/determines/detects the intensity of incident light. For example, polarization camera 260 may include a number of CCD pixels that receive incident light and generate an electrical signal corresponding to an intensity of the incident light at each of the number of CCD pixels. For example, polarization camera 260 may include CCD sensor 262. In various embodiments, polarization camera 260 is similar to image sensor 160. Polarization camera 260 may include micro-polarization array 270. Micro-polarization array 270 may include a number of micro-polarizers that polarize incident light before it reaches the image sensor of polarization camera 260. For example, micro-polarization array 270 may include four micro-polarizers oriented at −45°, 0°, 45°, and 90° (e.g., relative to an axis of polarization camera 260, etc.) for each pixel of polarization camera 260.

In various embodiments, metalens 240 modifies/processes/manipulates incident light from object 210 to produce one or more images 202 on a surface of polarization camera 260. For example, metalens 240 may produce a first image having a first position on a surface of polarization camera 260 and may produce a second image having a second position of the surface of polarization camera 260 that is offset from the first position. In various embodiments, the one or more images 202 produced by metalens 240 have different characteristics. For example, metalens 240 may produce a first image on a surface of polarization camera 260 having a first polarization (e.g., polarized in a 0° orientation, etc.) and may produce a second image (e.g., at least partially overlapping with or overlaying on the first image) on a surface (e.g., same surface) of polarization camera 260 having a second polarization (e.g., polarized in a 90° orientation, etc.). As another example, metalens 240 may produce a first image on a surface of polarization camera 260 having a first point spread function (PSF) and may produce a second image on a surface of polarization camera 260 having a second PSF than the first PSF. In various embodiments, the one or more images 202 at least partially overlap on the surface, and/or are spatially offset with each other, but may have similar/same size and/or orientation for instance. In various embodiments, polarization camera 260 measures one or more characteristics of the one or more images 202. For example, polarization camera 260 may generate first measurement 204 of an intensity associated with a first image having a first polarization and may generate second measurement 206 of an intensity associated with a second image having a second polarization that is different than the first polarization.

In various embodiments, system 200 performs operation 208 using first measurement 204 and second measurement 206 to produce net image 280. In various embodiments, operation 208 includes a pixel by pixel (e.g., intensity-based) subtraction of a first image associated with first measurement 204 from a second image associated with second measurement 206. In various embodiments, net image 280 is a filtered (e.g., spatial frequency filtered) version of an image captured by polarization camera 260. For example, net image 280 may include the high-frequency components of an image captured by polarization camera 260. In various embodiments, system 280 uses net image 280 to determine depth and/or edges associated with object 210.

Referring now specifically to FIG. 2B, scatterplots of design characteristics of metalens 240 are shown, according to an example embodiment. In various embodiments, metalens 240 implements an inverse-designed pair of phase-profiles. In various embodiments, backpropagation using a spatial gradient of field values is used to obtain design parameters (e.g., one or more of the phase-profiles, etc.). Plot 250 illustrates the local phase-shift imparted by metalens 240 in response to x- and y-linearly polarized light. Each point corresponds to a nanostructure with a different length (L) and width (W), as shown in plot 252 by the 2D greyscale-map. Determining the design characteristics of metalens 240 is described in greater detail below.

In various embodiments, a 2D complex field of an output of an arbitrary optical system, denoted by coordinates (u, v), may be described at the input plane, (ξ, η), via the convolution equation:

$${U}_{0} ( u , v ) = {{\int \int }_{- ∞}}^{+ ∞} h ( u - ξ , v - η ) {U}_{i} ( ξ , η ) d ξ d η$$

where subscripts 0 and i denote the output and input fields, respectively, and h(u, v; ξ, η) is the complex amplitude point-spread function of the system, dependent on the phase, transmittance, and location of all optical components placed between the input and output. In various embodiments, the (time averaged) output intensity field may be given as:

$${I}_{0} ( u , v ) = κ {{\int \int }_{- ∞}}^{+ ∞} {\vert h ( u - ξ , v - η ) \vert}^{2} {I}_{i} ( ξ , η ) d ξ d η$$

where κ is some real constant. The quantity |h|² is the intensity point spread function (IPSF) for a spatially incoherent imaging system and describes how the intensity at a single point in the input is transformed at the output. The Fourier transform of the (time averaged) output intensity field is:

$${\tilde{I}}_{i} ( u , v ) = ℱ \{ {\vert h ( u - ξ , v - η ) \vert}^{2} \} {\tilde{I}}_{0} ( ξ , η )$$

where Ĩ denotes the Fourier transform of the field. In various embodiments, the IPSF specifies the redistribution of intensity in space when going from the input to the output plane. In various embodiments, the Fourier transform of the IPSF, referred to as the optical transfer function (OTF), specifies the same transformation in terms of the complex rescaling of each spatial frequency component in the image. In various embodiments, an optical system, incoherent or coherent, may be associated with a particular spatial frequency filtering operation. For incoherent light this operation may be fully defined via the OTF.

In various embodiments, a net image produced by the subtraction of two intensity distributions, each formed by a different IPSF may be considered. The net image may be described via the convolution of the IPSFs and the intensity distribution at the input plane:

$${I}_{0}^{net} ( u , v ) = κ {{\int \int }_{- ∞}}^{+ ∞} [ {\vert {h}_{1} ( u - ξ , v - η ) \vert}^{2} - {\vert {h}_{2} ( u - ξ , v - η ) \vert}^{2} ] x {I}_{i} ( u , v ) d ξ d η$$

where x denotes multiplication. The net image, formed by a digital subtraction after measuring the two intensity fields, may be equivalent to the single image that would be produced from a hypothetical optical system with an IPSF equal to the bracketed term above. In various embodiments, the net OTF is derived via the Fourier transform of this net IPSF:

$$Net OTF = ℱ [ {\vert {h}_{1} \vert}^{2} - {\vert {h}_{2} \vert}^{2} ]$$

In various embodiments, limitations of the OTF structure are eased with respect to the net image as the output of the optical system, rather than the individual images. In various embodiments, while the net OTF displays Hermitian symmetry, the 2D filtering operation implemented by the system may be free of the constraint of maximal transfer for the zero spatial frequency component by virtue of a real but bipolar net IPSF. In various embodiments, systems and methods of the present disclosure may facilitate a substantial class of spatial frequency operations including image differentiation in the digitally subtracted image through co-design of the two IPSFs.

In various embodiments, the optical filtering system of the present disclosure may utilize inverse design to determine one or more phase profiles that implement a desired filtering operation. In various embodiments, an IPSF for an optical system comprising a single thin lens (e.g., a metasurface such as metalens 340, etc.) with a spatially-varying complex phase profile P(x, y) and real transmittance T(x, y) is derived. In some embodiments, assuming an ideal point-source at a distance z₀ in front of the lens as the input and an output plane at a distance z_{d} after, the amplitude point-spread function can be given via Fourier optics as:

$$h ( u , v ; {ξ}^{′} , {η}^{′} ) = \frac{c}{{λ}^{2} {z}_{d} {z}_{0}} {{\int \int }_{- ∞}}^{+ ∞} [ P ( x , y ) T ( x , y ) {e}^{( \frac{ik}{2} ( {x}^{2} + {y}^{2} ) ( \frac{1}{{z}_{0}} + \frac{1}{{z}_{d}} ) )} ] * exp \{ - i 2 π [ ( \frac{u - {ξ}^{′}}{λ {z}_{d}} ) x + ( \frac{v - {η}^{′}}{λ {z}_{d}} ) y ] \} dxdy$$

where c is a constant combining the complex terms dependent on (u, v) and (ξ′, η′) and is removed when converting to the IPSF. In deriving the above equation, the paraxial approximation of the spherical wavefront incident on the lens front may be assumed. In various embodiments, the geometric magnification term M=−z_{d}/z₀ emerges in the expression. However, this term may be removed from the point-spread function definition by introducing the rescaled input coordinates ξ′=Mξ and η′=Mη. Therefore, the intensity field Iᵢ(ξ, η) (shown above) may be replaced with a rescaled input intensity field such that the image formation model is given via

$${I}_{0} ( u , v ) = κ {{\int \int }_{- ∞}}^{+ ∞} {\vert h ( u - {ξ}^{′} , v - {η}^{′} ) \vert}^{2} [ \frac{1}{\vert M \vert} {I}_{i} ( \frac{{ξ}^{′}}{M} , \frac{{η}^{′}}{M} ) ] d {ξ}^{′} d {η}^{′}$$

In various embodiments, the rescaled image term given in the brackets above is the geometrical-optics prediction of the image formed by a perfect imaging system (e.g., it is the image that would be produced by an ideal pinhole rather than a lens, etc.). Therefore, one of skill in the art can appreciate that the optoelectronic filtering system thus conducts spatial frequency filtering on the so-called pinhole image that is captured on the photodetector rather than the exact intensity field at the input. This interpretation is convenient as the alternative digital filtering operation may equivalently be conducted on a captured, in-focus image.

By substituting the equations above, an expression relating a pair of lens profiles to the resulting net OTF is obtained. One of skill in the art can appreciate that opto-electronic incoherent frequency filtering may be achieved by simultaneously and efficiently implementing the two co-designed profiles and extracting each of the two images produced at the detector (e.g., as implemented by system 200). Specifically, in various embodiments, system 200 may include a single-metalens that implements two phase profiles on the same lens but on orthogonal linear polarization states of light. In various embodiments, although the two images spatially overlap at the detector plane, each can be simultaneously measured utilizing a polarization camera (e.g., an off-the-shelf polarization camera, etc.).

Referring now again to FIGS. 2A-2B, system 200 is shown to demonstrate the proposed functionality. In various embodiments, system 200 includes a 1 mm diameter metalens comprising dielectric TiO₂ nanofins patterned on a thin SiO₂ wafer. However, it should be understood that the metalens may be any size and/or shape. In various embodiments, the nanofin is the fundamental building block of the lens. However, it should be understood that other nanostructures are possible such as nanopillars and the like. In various embodiments, a center-to-center distance of each nanofin on the wafer is fixed at 350 nm for operation in the visible regime. However, it should be understood that other dimensions are possible. In various embodiments, each nanofin has a uniform height of 600 nm, thereby enabling fabrication with single-step lithography. However it should be understood that other dimensions are possible. In various embodiments, because of the subwavelength scale, each nanofin physically functions as a truncated waveguide imparting a local phase-shift on the wave-front without introducing higher-order diffraction. In various embodiments, the nanofins display shape birefringence. Additionally or alternatively, the nanofins may introduce a different effective index of refraction and/or local phase shift for incident light linearly-polarized along each direction (e.g., by selectively tuning the length of the nanofin along the (W) x- and (L) y-axis, etc.). In various embodiments, nanofin dimensions may be determined to encode the two desired phase profiles. The required phase profiles may be wrapped to [0, 2π] without affecting the IPSFs, thereby facilitating polarization-sensitive local-phase shift between 0 and 2π for precise wavefront shaping. In various embodiments, the metalens is spatially-varied. For example, the metalens may include a number of physical structures (e.g., TiO₂ nanofins, etc.) that differ in shape, size, and/or composition across the metalens. In various embodiments, the term spatially-varying as used herein refers to a parameter that changes (e.g., varies) in space (e.g., two-dimensional space, three-dimensional space, etc.). For example, a metalens may include a number of nanofins such as a first nanofin having a first set of dimensions and a second nanofin having a second set of dimensions.

In some embodiments, nanofin dimensions are identified from a library. For example, a library of nanofin elements may be generated for all combinations of nanofin length in x and y between 50 and 320 nm, with a step size of 10 nm. In various embodiments, the polarization-sensitive phase-shift for each nanofin element may be simulated via finite difference time domain (FDTD) analysis (e.g., where periodic boundary conditions are assumed and the unit-cell is illuminated via a plane-wave with the simulation wavelength sweeped across the visible spectrum, etc.). FIG. 2B illustrates the simulation results for the library at 532 nm incident wavelength (e.g., with all nanofin elements with a transmission less than 90% removed).

In some embodiments, a linear polarizer with a principal axis oriented 45° relative to the metasurface x-axis is positioned at the input of the camera to ensure that each polarization-encoded phase profile at the lens observes the same incident wavefront. Additionally or alternatively, a spectral filter may be included. In various embodiments, the two spatially overlapping optical fields are measured and decoupled with a polarization sensitive image sensor. Such image sensors may include an array of micro-scale polarization filters oriented at different angles and positioned above the image sensor pixels, thereby enabling different pixels to capture each of the two images. Therefore, a single camera measurement may capture the two images without a need for processing or reconstruction.

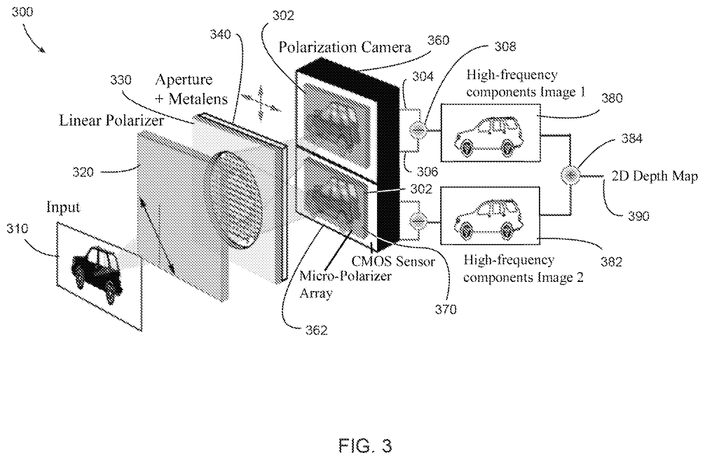

Referring now specifically to FIG. 3, system 300 for determining depth is shown, according to an example embodiment. In various embodiments, system 300 is similar to system 200 and/or system 100. System 300 is shown to include input 310, linear polarizer 320, aperture 330, metalens 340, and polarization camera 360. In various embodiments, input 310 is similar to object 110 and/or object 210. In various embodiments, linear polarizer 320 is similar to polarizer 120 and/or linear polarizer 220. In various embodiments, aperture 330 is similar to aperture 130 and/or aperture 230. In various embodiments, metalens 340 is similar to metalens 140 and/or metalens 240. In various embodiments, polarization camera 360 is similar to image sensor 160 and/or polarization camera 260.

In various embodiments, polarization camera 360 includes CMOS sensor 362. In various embodiments, micro-polarizer 370 may be positioned between CMOS sensor 362 and incident light. In various embodiments, micro-polarizer 370 is similar to micro-polarizer 170. In various embodiments, metalens 340 receives incident light and modifies the incident light to produce a number of images 302 on a surface of polarization camera 360. For example, metalens 340 may receive incident light and modify the incident light to produce two sets of images 302 on a surface of polarization camera 360. In various embodiments, the two sets of images 302 are spatially distributed. For example, a first set of images may be positioned on a first portion of polarization camera 360 and a second set of images may be positioned on a second portion of polarization camera 360. In some embodiments, each set of images includes one or more images. The one or more images may have different characteristics. For example, a first image of a first set of images may have a first position and a first PSF and a second image of the first set of images may have a second position and a second PSF. In various embodiments, metalens 340 simultaneously generates four images from a single input. For example, metalens 340 may receive incident light and modify the incident light to simultaneously produce two sets of two images, each on different portions of polarization camera 360.

In various embodiments, polarization camera 360 generates first measurement 304 and second measurement 306 corresponding to each image in a set of images. For example, polarization camera 360 may measure an intensity at each pixel of a first image of a first set of images, a second image of the first set of images, a first image of a second set of images, and a second image of the second set of images. In various embodiments, system 300 performs operation 308 with one or more of the measurements to produce outputs 380 and 382. For example, for each pair of images, system 300 may perform a pixel by pixel subtraction of the images in the set of images. In various embodiments, operation 308 is performed digitally. Additionally or alternatively, operation 308 may be performed in analog (e.g., by a circuit configured to subtract an analog signal such as a voltage representing a first measurement from an analog signal representing a second measurement, etc.). In various embodiments, outputs 380 and 382 may be images that have a spatial frequency filter applied. For example, outputs 380 and 382 may be high-frequency components of an image projected on a surface of polarization camera 360.

In various embodiments, system 300 performs operation 384 using outputs 380 and 382 to generate 2D depth map 390. In various embodiments, operation 384 includes a division operation (e.g., pixel-by-pixel division, etc.). In some embodiments, operation 384 is performed digitally. 2D depth map 390 may include depth information relating to input 310. For example, 2D depth map 390 may include a depth associated with each pixel in an image measured by polarization camera 360. In various embodiments, the depth information describes a distance from a reference point associated with system 300 to an element in a scene of input 310. For example, input 310 may include a scene of a vehicle and 2D depth map 390 may include depth information describing a distance from polarization camera 360 to a point on a handle of the vehicle in the scene (e.g., a pixel illustrating such feature, etc.) and a point on a tire of the vehicle in the scene.

One of skill in the art can appreciate that, using the systems and methods described above, the net OTF, which defines the image transformation in frequency space, given two phase profiles is obtainable. Moreover, it can be appreciated that the mathematical relation between the net OTF and the two phase profiles is fully differentiable. Therefore, in various embodiments, a target net OTF may be specified and a phase-profile pair may be determined using gradient descent optimization.

As a non-limiting example, a phase profile pair may be determined for a 2D flat bandpass spatial frequency filter which transmits equally all spatial frequency components between 5 and 15 lp/mm in the net image and removes all other components. Specifically, the |Net OTF|² (typically referred to as the modulation transfer function (MTF)) may be optimized against the target filter structure. In various embodiments, spatial frequency components transmitted by the opto-electronic system may be spatially shifted by up to one period in the net image, relative to in the pinhole image by neglecting the imaginary part of the OTF. In various embodiments, the two phase profiles are optimized at a resolution of 350 nm. However, it should be understood that other resolutions are possible. In this example, the metasurface is discretized into pixels of 4 μm.

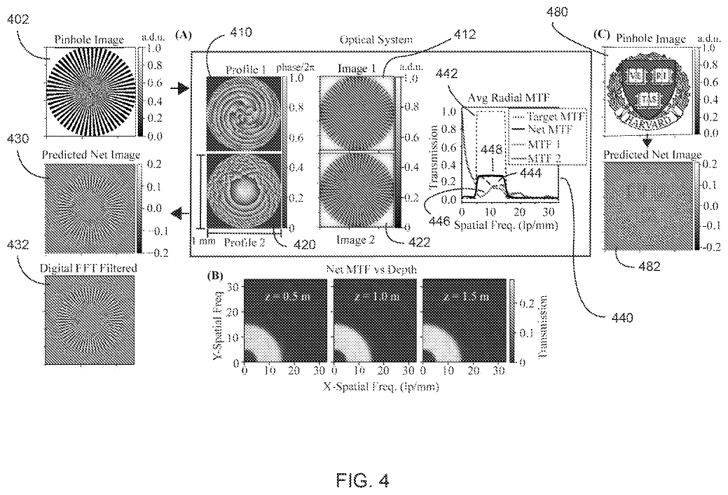

Referring now specifically to FIG. 4, optimization results are shown, according to an example embodiment. First phase profile 410 and second phase profile 420 are shown. In various embodiments, first phase profile 410 is associated with first image 412 and first MTF 446 and second phase profile 420 is associated with second image 422 and second MTF 444. In various embodiments, first MTF 446 and second MTF 444 form net MTF 448 which is similar to target MTF 442 (e.g., a flat bandpass), as shown in graph 440. In various embodiments, first image 412 and second image 422 result from modifying pinhole image 402 using one or more phase profiles (e.g., first phase profile 410 and second phase profile 420, etc.). Also shown are the 2D net MTF for three object to lens distances z₀ within the optimization range (e.g., illustrating depth invariant filtering performance). In various embodiments, pinhole image 402 (e.g., a Siemens star pattern placed a distance of 1 m in front of the metalens as the input intensity distribution) is used to validate the functionality of this system. Specifically, a metalens implementing first phase profile 410 and second phase profile 420 modifies pinhole image 402 to produce first image 412 and second image 422 respectively. In various embodiments, subtracting first image 412 from second image 422 produces predicted net image 430. In various embodiments, predicted net image 430 illustrates an effective transmission of only spatial frequency components within the bandpass shown in graph 440. For comparison, digital FFT filtered image 432 illustrates a conventional method of obtaining a filtered image through digital filtering (e.g., via taking the fast Fourier transform (FFT), multiplying by the target binary bandpass mask, and then taking the inverse FFT to get the filtered image back in the spatial domain). As another example, pinhole image 480 is modified using the systems and methods described herein to generate predicted net image 482 (e.g., implementing an optical bandpass filter). In various embodiments, systems and methods of the present disclosure facilitate generating one or more phase profiles to implement a spatial frequency filter using an inverse-design process. The inverse-design process including backpropagation is discussed in U.S. Provisional Patent Application No. 63/140,260 filed on Jan. 22, 2021, the entire disclosure of which is incorporated by reference herein. In various embodiments, backpropagation as used herein refers to utilizing one or more parameters (e.g., a spatial gradient of field values, etc.) to obtain design parameters (e.g., values corresponding to a phase profile, nanopillar dimensions, etc.) to achieve an outcome (e.g., implement a spatial frequency filter, etc.). For example, system and methods of the present disclosure may facilitate determining a relationship between one or more phase profiles and spatial frequency characteristics of electromagnetic radiation manipulated by the one or more phase profiles and performing backpropagation (e.g., using a fully differentiable relationship, etc.) according to the relationship to obtain a plurality of phase values for the one or more phase profiles to implement a filter.

Speaking now generally, the effects of phase errors on image processing performance are discussed. In some embodiments, the metalens may be designed directly by matching the pair of phase values at each pixel to a particular birefringent nanofin structure. Additionally or alternatively, the optimized profiles may be resampled to match optimization discretization with the unit cell size.

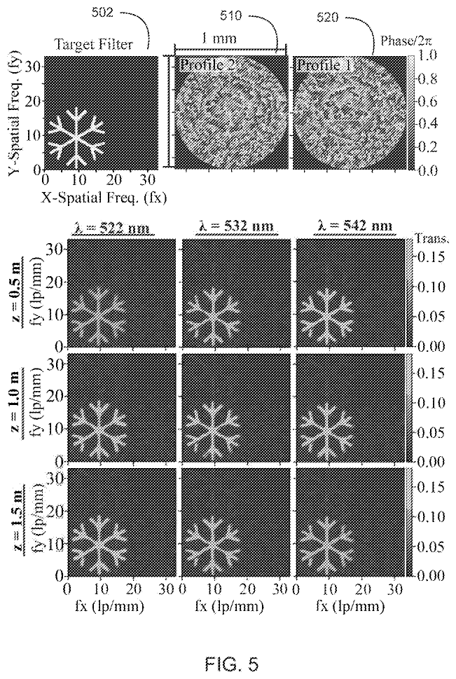

One of skill in the art can appreciate that the inverse-design metalens approach of the present disclosure may facilitate a broad range of frequency operations. For example, FIG. 5 illustrates a snowflake structure in frequency space as the target frequency operation along with the net MTF computed for different z₀ and A values. In various embodiments, the snowflake shown in target filter 502 represents spatial frequency components that are retained with all other components removed. For example, first phase profile 520 and second phase profile 510 may implement target filter 502. In some embodiments, constraints may be introduced in the optimization, enforcing solutions to the phase-filter inverse problem that display not only a depth-invariance of the net MTF within a 1 m range but also a broadband functionality for wavelengths of 532±10 nm (e.g., by computing the net MTF for multiple combinations of z₀ and λ within the user specified range during each iteration and averaging the loss function for each, etc.).

In various embodiments, the systems and methods of the present disclosure may facilitate computing derivatives of an image. For example, derivatives may be calculated with a single digital subtraction operation. It should be appreciated that a derivative in the spatial domain along the u coordinate axis corresponds to multiplication in the frequency domain by the operator i2πu. This is derived directly by noting that:

$$ℱ \{ \frac{\partial I ( u , v )}{\partial u} \} = i 2 π u ℱ \{ I ( u , v ) \}$$

Using the equations above, it can be determined that an exact derivative of the pinhole image is obtained in the net image if the net OTF of the system is proportional to the quantity ifₓ, where fₓ=u/(λz_{d}). In various embodiments, generalizing to higher order derivative operations of the form on ∂ⁿ/∂uⁿ, it can be summarized that the imaginary component of the net OTF may be designed to be an odd function for odd n values and an even function for even n. In various embodiments, the gradient descent optimization method described above may be used to determine the appropriate design characteristics. For example, a metalens implementing a 1D first-derivative of the ideal pinhole image may be generated.

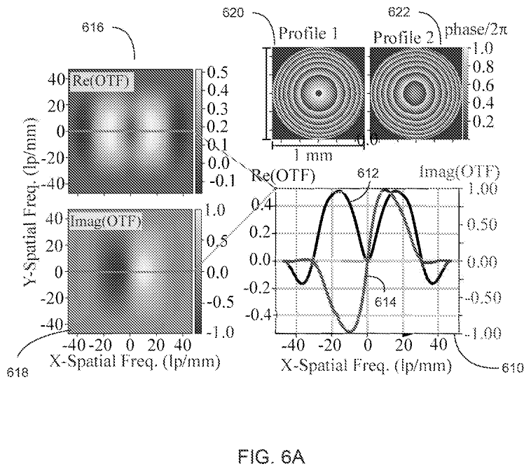

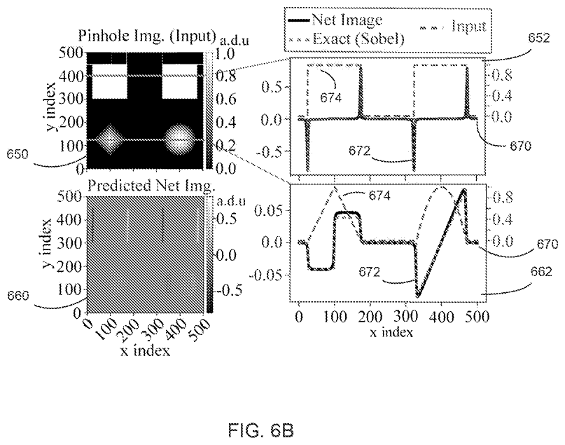

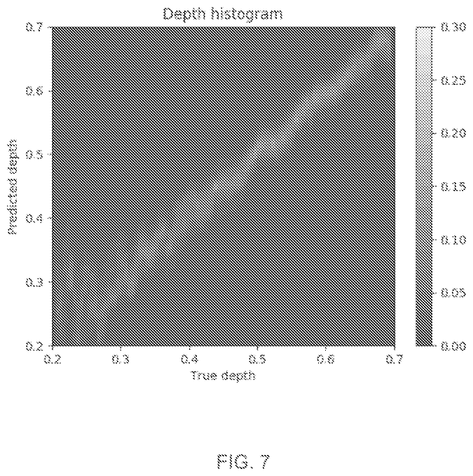

Referring specifically to FIGS. 6A-6B, image differentiation using metalens filtering is shown, according to an example embodiment. In various embodiments, i, which corresponds to a x-phase discontinuity about fₓ=0, is reproduced in imaginary component 614 of net OTF 610. Net OTF 610, implemented by first phase profile 620 and second phase profile 622, may include real component 612 and/or imaginary component 614 with corresponding real OTF 616 and imaginary OTF 618, respectively. FIG. 6A illustrates an odd phase response. In various embodiments, the structure is enforced for fₓ between 0 and 15 lp/mm. In various embodiments, net OTF 610 is designed to closely approximate a linear function of spatial frequency along x. FIG. 6B illustrates predicted net image 660 generated using the optical filtering method described above. In various embodiments, input image 650 is modified using the generated metalens implementing first phase profile 620 and second phase profile 622 to produce predicted net image 660. First graph 652 illustrates characteristics of input image 650 at the first line corresponding to y-index=400. Second graph 662 illustrates characteristics of input image 650 at the second line corresponding to y-index=˜120. In various embodiments, first graph 652 illustrates the intensity along the first line and second graph 662 illustrates the intensity along the second line. As can be seen in second graph 662, net image 670 is compared to a purely digital calculation of the first derivative (e.g., implemented by convolution with the Sobel kernel) shown by exact 672 and input 674. It should be appreciated that the opto-electric approach used to produce predicted net image 660 aligns with traditional digital implementations while requiring approximately 2*10⁶ fewer floating point operations, thereby saving a significant amount of computing resources. In various embodiments, exact 672 is a derivative of input 674.

Turning now to FIG. 7, a graph illustrating depths determined using the systems and methods of the present disclosure are shown, according to an example embodiment. In various embodiments, the opto-electric approach can require less computation and can introduce a larger operational depth range than current “depth from defocus” methods. For example, a traditional stereovision system may require 2,500 to 7,000 FLOPs per pixel while the opto-electric approach may utilize 3 FLOPs per pixel.

In summary, the present disclosure illustrates systems and methods of snapshot incoherent image processing based on polarization-multiplexing of a metalens. In various embodiments, the opto-electronic imaging architecture facilitates a general class of user-specified 2D spatial frequency filtering operations on an image with only a single pixel-by-pixel digital subtraction. In various embodiments, one or more phase profiles are generated via inverse design. The one or more phase profiles may facilitate image differentiation and may reduce the computational cost for edge-detection (e.g., as compared with traditional digital filtering techniques such as in computer-vision systems, etc.). By implementing the one or more phase profiles using a metalens, systems and methods of the present disclosure may facilitate low-computation depth sensors and 3D imaging systems and may replace expensive mathematical operations with the opto-electronically enabled subtraction.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to #1%, less than or equal to +0.5%, less than or equal to +0.1%, or less than or equal to +0.05%. For example, two numerical values can be deemed to be “substantially” the same or equal to each other if a difference between the values is less than or equal to +10% of an average of the values, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A sensor for determining a physical characteristic, comprising:
a linear polarizer;
a polarization-sensitive metalens, positioned between the linear polarizer and a photosensor, configured to manipulate light from a scene filtered by the linear polarizer, according to two or more phase profiles to simultaneously produce at least two images on a surface of the photosensor; and
processing circuitry configured to:
receive, from the photosensor, a measurement corresponding to the at least two images; and
determine, according to the measurement, a physical characteristic associated with at least one feature in the scene.

2. The sensor of claim 1, wherein the light includes light having a first polarization and wherein the linear polarizer manipulates the light to produce first light having a first polarization state and second light having a second polarization state.

3. The sensor of claim 1, wherein the photosensor is a polarization-sensitive photosensor.

4. The sensor of claim 3, wherein a first image of the at least two images produced by the polarization-sensitive metalens includes light of a first polarization and wherein a second image of the at least two images includes light of a second polarization.

5. The sensor of claim 4, wherein the measurement includes a first intensity measurement corresponding to the light of the first polarization and a second intensity measurement corresponding to the light of the second polarization.

6. The sensor of claim 5, wherein determining the physical characteristic comprises determining depth associated with the at least one feature by performing greater than two floating point operations (FLOPs) per pixel.

7. The sensor of claim 1, wherein the light from the scene includes spatially incoherent light.

8. A method of generating design parameters to implement a filter, comprising:
determining a relationship between (i) two or more phase profiles each comprising a plurality of phase values and (ii) spatial frequency characteristics of electromagnetic radiation manipulated by the two or more phase profiles;
performing backpropagation using the relationship to obtain a first plurality of phase values for a first phase profile of the two or more phase profiles and a second plurality of phase values for a second phase profile of the two or more phase profiles, wherein the first plurality and the second plurality of phase values collectively at least partially implement the filter; and
generating a first set of design parameters that implement the first plurality of phase values and a second set of design parameters that implement the second plurality of phase values.

9. The method of claim 8, wherein the first set and the second set of design parameters include at least a value of a diameter, height, or width of a nanopillar.

10. The method of claim 8, further comprising combining the first set and the second set of design parameters to obtain two dimensions of a physical structure.

11. The method of claim 10, wherein the physical structure includes a spatially-varying metalens.

12. The method of claim 8, wherein the first phase profile is configured to selectively manipulate electromagnetic radiation having a first polarization and wherein the second phase profile is configured to selectively manipulate electromagnetic radiation having a second polarization.

13. The method of claim 8, wherein the first plurality of phase values implement a first filter, the second plurality of phase values implement a second filter, and applying an operation on intensity values of electromagnetic radiation manipulated by the first plurality and the second plurality of phase values, at least partially implements the filter.

14. The method of claim 13, wherein the operation includes subtraction.

15. An attachment for a polarization-sensitive imaging device, comprising:
a polarization-sensitive metalens, positioned between a filter and a photosensor, configured to manipulate light from a scene filtered by the filter according to two or more phase profiles to simultaneously produce at least two images on a surface of the photosensor; and
wherein each of the two or more phase profiles implemented by the polarization-sensitive metalens apply a spatial frequency filter to manipulate the filtered light.

16. The attachment of claim 15, wherein the light includes light having a first polarization and wherein the filter manipulates the light to produce first light having a first polarization state and second light having a second polarization state.

17. The attachment of claim 15, wherein a first image of the at least two images produced by the polarization-sensitive metalens includes light of a first polarization state and wherein a second image of the at least two images includes light of a second polarization state.

18. The attachment of claim 17, wherein the polarization-sensitive imaging device is configured to measure an intensity associated with the at least two images, the measurement including a first intensity measurement corresponding to the light of the first polarization state and a second intensity measurement corresponding to the light of the second polarization state.

19. The attachment of claim 18, wherein the polarization-sensitive imaging device is configured to determine a depth associated with at least one feature in the scene using the measurement, wherein determining the depth includes performing greater than two floating point operations (FLOPs) per pixel.

20. The attachment of claim 15, wherein the light from the scene includes spatially incoherent light.
